(19) United States
(12) Patent Application Publication
(10) Pub. No.: US 2025/0377586 A1
(43) Pub. Date: Dec. 11, 2025

(54) SHAPING APPARATUS AND ARTICLE MANUFACTURING METHOD

(71) Applicant: CANON KABUSHIKI KAISHA, Tokyo (JP)

(72) Inventor: SHINTARO NARIOKA, Tochigi (JP)

(21) Appl. No.: 19/226,857

(22) Filed: Jun. 3, 2025

(30) Foreign Application Priority Data
Jun. 7, 2024 (JP) 2024-093204

(51) Int. Cl. G03F 7/00; H01L 21/687

(52) U.S. Cl. CPC G03F 7/0002; H01L 21/68764

(57) ABSTRACT

The present disclosure provides a shaping apparatus for shaping a composition on a substrate using a mold, comprising: a stage configured to move while holding the substrate; and an electrically-conductive member protruding from the stage to remove an electric-charge from the mold in a non-contact manner, wherein the electrically-conductive member is configured to approach the mold by the movement of the stage and cause discharge from the mold.

### BACKGROUND

### Field of the Technology

The present disclosure relates to a shaping apparatus and an article manufacturing method.

### Description of the Related Art

An imprint technique is a technique capable of transferring nanoscale micropatterns, and is beginning to be put into practical use as one nanolithography technique for mass-production of magnetic storage media or semiconductor devices. In the imprint technique, a mold on which a micropattern is formed is used as an original, and the micropattern is formed on a substrate such as a silicon wafer or a glass plate. More specifically, the micropattern made of a cured product of a composition (imprint material) can be formed on a substrate by supplying the composition onto the substrate, curing the composition in a state in which the composition on the substrate and a mold are in contact with each other, and separating the mold from the cured composition.

In the imprint technique, a phenomenon called separation charging occurs, in which a mold is charged by an operation of separating the mold from a cured composition on a substrate. If the mold is in the charged state, surrounding particles (foreign substances) are attracted and adhered to the mold, and the mold to which the particles are adhered is brought into contact with the composition on the substrate in subsequent pattern formation. As a result, a defect may occur in a pattern formed on the substrate, thereby making it difficult to accurately shape the composition on the substrate. Japanese Patent Laid-Open No. 2019-41004 describes a method of removing an electric-charge from a mold by irradiating the mold with radiation such as α-rays or soft X-rays.

If radiation such as α-rays or soft X-rays is used, as in the method described in Japanese Patent Laid-Open No. 2019-41004, it is necessary to cope with regulations for preventing radiation leakage, and thus an apparatus configuration becomes complex.

### SUMMARY

The present disclosure is directed to provide, for example, a technique advantageous in efficiently removing an electric-charge from a mold with a simple configuration.

According to one aspect of the present disclosure, there is provided a shaping apparatus for shaping a composition on a substrate using a mold, comprising: a stage configured to move while holding the substrate; and an electrically-conductive member protruding from the stage to remove an electric-charge from the mold in a non-contact manner, wherein the electrically-conductive member is configured to approach the mold by the movement of the stage and cause discharge from the mold.

Features of the present disclosure will become apparent from the following description of embodiments with reference to the attached drawings. The following description of embodiments are described by way of example.

### BRIEF DESCRIPTION OF THE DRAWINGS

FIG. 1 is a schematic view showing an example of the configuration of an imprint apparatus according to the first embodiment;

FIG. 2 is a view showing an example of the arrangement of static charge eliminators on a stage;

FIG. 3 is a schematic view showing an example of the configuration of an imprint apparatus according to the second embodiment;

FIG. 4 is a schematic view showing an example of the configuration of an imprint apparatus according to the third embodiment;

FIG. 5 is a flowchart illustrating an imprint process;

FIG. 6 is a schematic view showing an example of the configuration of a planarization apparatus according to the fourth embodiment;

FIGS. 7A to 7F are views for explaining an article manufacturing method using the imprint apparatus; and

FIGS. 8A to 8D are views for explaining an article manufacturing method using the planarization apparatus.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface of a substrate are defined as the X-Y plane, unless otherwise specified. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and a posture is information that can be specified by values on the θX-, θY-, and θZ-axes.

A shaping apparatus according to the present disclosure is an apparatus that performs a shaping process of shaping a composition on a substrate using a mold. Examples of the shaping apparatus are an imprint apparatus and a planarization apparatus. The imprint apparatus is an apparatus that brings a mold including a concave-convex pattern into contact with a composition (imprint material) on a substrate to form (transfer) the pattern on the composition. The shaping process performed by the imprint apparatus will sometimes be referred to as an imprint process hereinafter. The planarization apparatus is an apparatus that planarizes the surface of a composition on a substrate by bringing a mold including a flat surface into contact with the composition. The shaping process performed by the planarization apparatus will sometimes be referred to as a planarization process hereinafter. The imprint apparatus will be exemplified as the shaping apparatus below, but the configuration and process of the imprint apparatus can also be applied to the planarization apparatus.

### First Embodiment

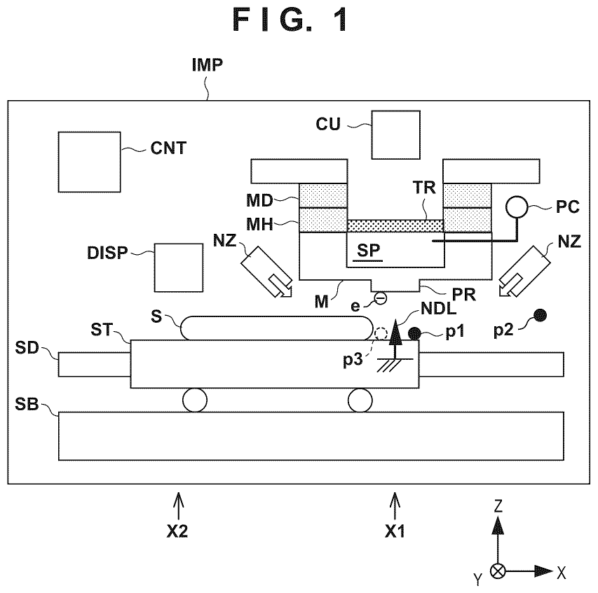

The first embodiment according to the present disclosure will be described. FIG. 1 is a schematic view showing an example of the configuration of an imprint apparatus IMP according to this embodiment. The imprint apparatus IMP is a lithography apparatus that shapes an imprint material (composition) on a substrate using a mold M and can be employed for a lithography step that is a manufacturing step for a magnetic storage medium or a semiconductor device. The imprint apparatus IMP brings an uncured imprint material supplied onto the substrate S into contact with the mold M and gives the imprint material with curing energy, thereby performing a process of forming, on the substrate S, the pattern of a cured product obtained by transferring the pattern of the mold M. This process is called an imprint process and is performed for each of a plurality of shot regions (imprint regions) on the substrate S. This embodiment will describe an example of employing a photo-curing method of curing an imprint material on the substrate S by irradiating the imprint material with light (ultraviolet light).

Here, the mold M and the substrate S are interchangeable, and the pattern of the mold M may be formed (transferred) on a film of the imprint material filled in the space between the mold M and the substrate S by bringing the imprint material arranged on the mold M into contact with the substrate S. Therefore, the imprint apparatus IMP is comprehensively an apparatus that executes a process of curing a composition on a second member in a state in which a first member and the composition are in contact with each other, and separating the first member from the cured composition, thereby forming the pattern on the composition on the second member. That is, the imprint apparatus IMP functions as an imprint means (film forming means) for performing a film forming process (film forming step) of forming a film of a composition, onto which the pattern of the first member is transferred, on the second member. This embodiment will explain an example in which the first member serves as the mold M and the second member serves as the substrate S. However, the first member may serve as the substrate S and the second member may serve as the mold M. In this case, the mold M and the substrate S in the following description are interchanged.

The mold M is generally manufactured by a material that can transmit light (ultraviolet light), such as silica glass. The mold M used in the imprint apparatus IMP includes, for example, a pattern region PR formed into a mesa shape having a step of about several tens of nm. The surface (pattern surface) of the pattern region PR on the substrate side includes a concave-convex pattern such as a circuit pattern to be transferred to the imprint material on the substrate S, and functions as a shaping surface (contact surface) which comes into contact with the imprint material on the substrate S to shape the imprint material. Note that in the mold used in the planarization apparatus, 90% or more (preferably, 95% or more) of the shaping surface (contact surface) that contacts the composition on the substrate to shape the composition is formed as a flat surface on which no concave-convex pattern is formed.

As the material of the substrate S, for example, glass, a ceramic, a metal, a semiconductor, a resin, or the like is used. A member made of a material different from the substrate S may be provided on the surface of the substrate S, as needed. The substrate S can be, for example, a silicon wafer, a compound semiconductor wafer, silica glass, or the like.

As the imprint material, a curable composition (to be also referred to as a resin in an uncured state) to be cured by receiving curing energy can be used. As the curing energy, an electromagnetic wave, heat, or the like can be used. The electromagnetic wave can be, for example, light selected from the wavelength range of 10 nm (inclusive) to 1 mm (inclusive), more specifically, infrared rays, visible light, or ultraviolet light. The curable composition can be a composition cured by light irradiation or heating. Among these, a photo-curable composition cured by light irradiation contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The viscosity (the viscosity at 25° C.) of the curable composition can be, for example, from 1 mPa's (inclusive) to 100 mPa's (inclusive).

The imprint apparatus IMP can include a stage ST (substrate holder) that moves while holding the substrate S, a substrate driving mechanism SD that drives the substrate S by driving the stage ST, and a support base SB that supports the substrate driving mechanism SD. In addition, the imprint apparatus IMP can include a mold holder MH that holds the mold M and a mold driving mechanism MD that drives the mold M by driving the mold holder MH.

The substrate driving mechanism SD can be configured to drive the substrate S with respect to a plurality of axes (for example, three axes including the X-axis, Y-axis, and θZ-axis, and preferably six axes including the X-axis, Y-axis, Z-axis, θX-axis, θY-axis, and θZ-axis) by driving the stage ST with respect to the plurality of axes. The mold driving mechanism MD can be configured to drive the mold M with respect to a plurality of axes (for example, three axes including the Z-axis, θX-axis, and θY-axis, and preferably six axes including the X-axis, Y-axis, Z-axis, θX-axis, θY-axis, and θZ-axis) by driving the mold holder MH with respect to the plurality of axes.

The substrate driving mechanism SD and the mold driving mechanism MD can form a relative driving mechanism that relatively drives the substrate S and the mold M so as to adjust the relative position between the substrate S and the mold M. Adjustment of the relative position by the relative driving mechanism can include driving to bring the imprint material on the substrate S and the mold M into contact with each other and driving to separate the mold M from the cured imprint material. In addition, adjustment of the relative position by the relative driving mechanism can include alignment between the substrate S and the mold M.

The imprint apparatus IMP can include a curing unit CU for curing the imprint material filled in the space between the substrate S and the mold M. For example, the curing unit CU can irradiate the imprint material on the substrate S with the curing energy (for example, ultraviolet light) via the mold M, thereby curing the imprint material. The imprint apparatus IMP can include a transmissive member TR for forming a space SP on the rear side (the opposite side of a surface opposing the substrate S) of the mold M. The transmissive member TR is made of a material that transmits the curing energy from the curing unit CU, thereby making it possible to irradiate a curable composition IM with the curing energy.

The imprint apparatus IMP can include a pressure controller PC that controls deformation of the mold M in the Z-axis direction by controlling the pressure of the space SP. For example, when the pressure controller PC makes the pressure of the space SP higher than the atmospheric pressure, the mold M can be deformed in a convex shape toward the substrate S.

The imprint apparatus IMP can include a dispenser DISP (liquid supplier) for supplying, arranging, or dispensing the imprint material as a plurality of droplets on the substrate S. However, the imprint apparatus IMP need not include the dispenser DISP. In this case, the substrate S to which the imprint material is supplied (applied) by an external apparatus can be loaded to the imprint apparatus IMP.

The imprint apparatus IMP can include a controller CNT that controls an imprint process. The controller CNT is implemented by, for example, a computer (information processing apparatus) including a processor such as a Central Processing Unit (CPU) and a storage unit such as a memory. The controller CNT controls each unit of the imprint apparatus IMP based on a computer program stored in the storage unit (memory) as a storage medium, thereby controlling the imprint process.

The imprint apparatus IMP having the above-described configuration sequentially executes the imprint process for each of the plurality of shot regions on the substrate S. In the imprint process, first, the substrate driving mechanism SD drives the stage ST to arrange the substrate S below the dispenser DISP, and the dispenser DISP supplies the imprint material onto the substrate S (liquid supply operation). After the end of the liquid supply operation, the substrate driving mechanism SD drives the stage ST to arrange the substrate S below the mold M. Next, the mold driving mechanism MD drives the mold M in the −Z direction to bring the pattern region PR (pattern surface) of the mold M into contact with the imprint material on the substrate S (contact operation). In the state in which the mold M and the imprint material on the substrate S are in contact with each other, the substrate S and the mold M are aligned, and then the curing unit CU cures the imprint material (curing operation). After that, the mold driving mechanism MD drives the mold M in the +Z direction to separate the mold M from the cured imprint material on the substrate S (mold-separating operation). This can form, on the substrate S, the pattern made of a cured product of the imprint material.

In the imprint process, a phenomenon called separation charging occurs, in which the mold Mis charged by the mold-separating operation of separating the mold M from the cured imprint material on the substrate S. If the mold Mis in the charged state, surrounding particles (foreign substances) are attracted and adhered to the mold M, and the mold M to which the particles are adhered is brought into contact with the imprint material on the substrate S in a subsequent imprint process. As a result, a defect occurs in the pattern formed on the substrate S, thereby making it difficult to accurately shape the imprint material on the substrate S.

FIG. 1 schematically shows a state in which the substrate driving mechanism SD drives the stage ST in the −X direction to execute the liquid supply operation for the next shot region after performing the mold-separating operation. As shown in FIG. 1, a negative electric-charge e is charged to the mold M having undergone the mold-separating operation by separation charging. In this embodiment, the polarity of the electric-charge e is negative, but may be positive. Based on a combination of the material of the mold M and the imprint material, it can be decided whether the mold M is easily charged positively or negatively.

A particle p1 adhered to the stage and a particle p2 floating in an atmospheric space can exist around the mold M. If the particles p1 and p2 and the mold M are charged in opposite polarities (positive and negative polarities), the particles p1 and p2 can be attracted to the mold M by an electrostatic force. If an imprint process of the next shot region is performed using the mold M to which the particles are adhered, a defect occurs in the pattern of the imprint material formed on the shot region. On the other hand, if an electric-charge is removed from the mold M, even if the particles p1 and p2 around the mold M are charged, the possibility that the particles p1 and p2 are attracted to the mold M is low, and thus it is possible to reduce adherence of the particles to the mold M.

The imprint apparatus IMP according to this embodiment includes an electrically-conductive member NDL for removing an electric-charge from the mold M in a non-contact manner. The electrically-conductive member NDL protrudes from the stage ST (for example, the upper surface of the stage ST), and is configured to approach the mold M by the movement of the stage ST to cause discharge from the mold M. That is, when the electrically-conductive member NDL is arranged near the mold M by the movement of the stage ST, discharge is caused between the mold M and the electrically-conductive member NDL. Removing an electric-charge from the mold M indicates reducing the amount of charge of the mold M, and is not intended to make the charge of the mold M completely disappear.

The electrically-conductive member NDL is made of an electrically-conductive material such as a metal or electrically-conductive ceramic, and protrudes from the stage ST (for example, the upper surface of the stage ST) to receive the electric-charge e emitted from the mold M. The electrically-conductive member NDL can have a shape with the pointed tip on the mold side (for example, a conical shape or needle shape) or a shape extending toward the mold side (for example, a columnar shape or rod shape). In particular, the electrically-conductive member NDL is formed in a needle shape with the pointed tip on the mold side. By sharpening the tip of the electrically-conductive member NDL and making the radius of curvature small, the field strength at the tip of the electrically-conductive member NDL becomes high. Even if the potential difference between the mold M and the electrically-conductive member NDL is small, it is possible to readily cause discharge and reliably remove an electric-charge from the mold M. The electrically-conductive member NDL formed in a needle shape will be exemplified below, and the electrically-conductive member NDL will sometimes be referred to as the “static charge eliminator NDL” hereinafter.

In the imprint apparatus IMP according to this embodiment, the stage ST can move between a shaping position X1 and a supply position X2, as shown in FIG. 1. The shaping position X1 is a position (first position) where the imprint material on the substrate S is shaped using the mold M, and may be understood as a position below the mold M (pattern region PR). The supply position X2 is a position (second position) where the imprint material is supplied onto the substrate S, and may be understood as a position below the dispenser DISP. The supply position X2 is in the −X direction (first direction) when viewed from the shaping position X1. The stage ST moves in the −X direction toward the supply position X2 to perform the liquid supply operation of the next shot region after the end of the mold-separating operation at the shaping position X1. In addition, the static charge eliminator NDL can be provided in the stage ST so as to approach the mold M during the movement of the stage ST from the shaping position X1 to the supply position X2 and cause discharge from the mold M. In this embodiment, the static charge eliminator NDL is grounded (that is, the static charge eliminator NDL is electrically connected to a ground portion (not shown)).

When the stage ST moves in the −X direction toward the supply position X2 (dispenser DISP), the static charge eliminator NDL provided in the stage S also moves together with the stage ST to approach the mold M in a non-contact state. At this time, the electric-charge e charged to the mold M can be emitted (discharged) to the static charge eliminator NDL. Since the static charge eliminator NDL is grounded, the electric-charge e emitted from the mold M flows into the ground portion, and is thus removed from the mold M. Since the static charge eliminator NDL approaches the mold M during the movement of the stage ST from the shaping position X1 to the supply position X2, the productivity (throughput) of the apparatus does not decrease. That is, with a simple configuration, the imprint apparatus IMP according to this embodiment can efficiently remove the electric-charge from the mold M charged by separation charging through the mold-separating operation without degrading the productivity of the apparatus.

The interval (the distance in the Z direction) between the static charge eliminator NDL and the mold M is desirably small. As the interval is smaller, discharge from the mold M to the static charge eliminator NDL can be caused more easily. For example, the interval between the mold M and the tip of the static charge eliminator NDL falls within the range of 10 μm to 100 mm. Note that the tip of the static charge eliminator NDL is desirably at a position farther than the surface (upper surface) of the substrate S when viewed from the mold M. That is, the tip of the static charge eliminator NDL is desirably at a position lower than the surface of the substrate S. Even if the imprint process (for example, the contact operation) is performed for the shot region in the peripheral portion of the substrate S, when the static charge eliminator NDL is configured/arranged as described above, it is possible to avoid the static charge eliminator NDL from contacting the surface of the mold M. That is, it is possible to prevent dust generation caused by contact between the mold M and the static charge eliminator NDL.

The distance in the X and Y directions between the static charge eliminator NDL and the substrate S is also desirably small. For example, assume a case where a particle p3 indicated by a broken line in FIG. 1 exists between the static charge eliminator NDL and the substrate S. In this case, concern about the particle p3 being attracted to the mold M by an electrostatic force before the static charge eliminator NDL approaches the mold M to remove the electric-charge from the mold M is increased. To avoid this, it is desirable to make the area between the static charge eliminator NDL and the substrate S on the upper surface of the stage ST as small as possible, thereby reducing the possibility that the particle is adhered to the portion between the static charge eliminator NDL and the substrate S on the upper surface of the stage ST. Therefore, the distance in the X and Y directions between the static charge eliminator NDL and the substrate S on the upper surface of the stage ST is desirably made as small as possible to the extent that the static charge eliminator NDL does not contact the substrate S.

Furthermore, as shown in FIG. 1, in the imprint apparatus IMP, a gas supplier NZ (nozzle) that supplies, to the periphery of the mold M, a gas (to be sometimes referred to as a discharge reducing gas hereinafter) for reducing (hindering) a discharge phenomenon from the mold M can be provided. As the discharge reducing gas, for example, a dry gas such as dry air is used. Discharge from the mold M is not always caused toward the static charge eliminator NDL. The mold M may discharge toward a member (for example, a grounded member) different from the static charge eliminator NDL in the apparatus via the gas around the mold M. If, for example, the humidity of the gas around the mold Mis high, the mold M may discharge toward a member different from the static charge eliminator NDL in the apparatus via moisture in the gas. In this case, depending on the material of the member as the discharge destination, there is a risk that the member will be damaged and some kind of dust will be produced.

To avoid this, it is desirable to reliably cause discharge from the mold to the static charge eliminator NDL. In this embodiment, as shown in FIG. 1, the gas supplier NZ can supply the discharge reducing gas to the periphery of the mold M, thereby replacing the periphery of the mold M by the discharge reducing gas. If the periphery of the mold M is filled with the discharge reducing gas, discharge via moisture in the gas is difficult to occur, and the possibility that the mold M discharges to the static charge eliminator NDL is increased. This can reduce concern about discharge from the mold M to the member different from the static charge eliminator NDL in the apparatus.

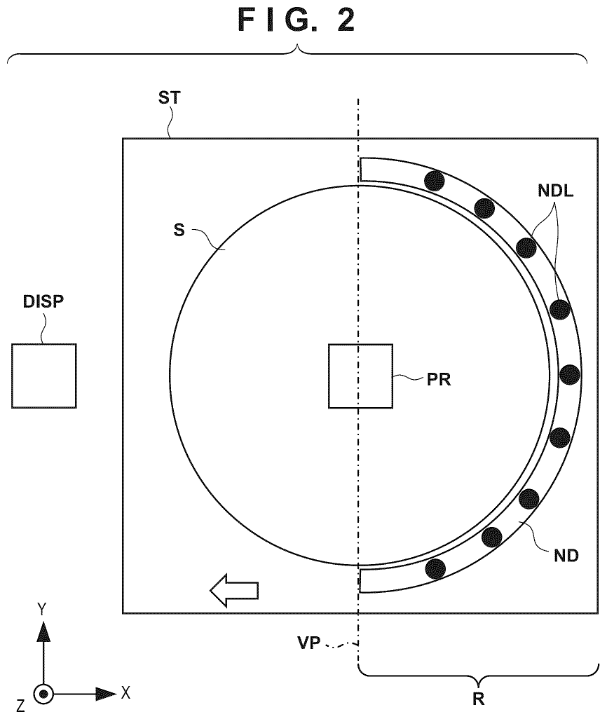

Next, the arrangement of the static charge eliminators NDL on the stage ST will be described. FIG. 2 is a plan view when viewing the stage ST and the dispenser DISP in the imprint apparatus IMP from above (the +Z direction side), and shows an example of the arrangement of the static charge eliminators NDL on the stage ST. FIG. 2 also shows the pattern region PR of the mold M.

In the imprint apparatus IMP according to this embodiment, the plurality of static charge eliminators NDL are provided on the stage ST. The plurality of static charge eliminators NDL can be arranged on the side of the substrate S in a second direction (+X direction) opposite to the first direction (−X direction) in which the stage ST moves from the shaping position X1 to the supply position X2 after the mold-separating operation. More specifically, when a virtual plane VP (Y-Z plane) perpendicular to the first direction and passing through the center of gravity (center) of the substrate S is defined, the plurality of static charge eliminators NDL can be arranged to surround the substrate S in a region R of the stage ST on the second direction side (+X direction side) of the virtual plane VP. The plurality of static charge eliminators NDL are arrayed along the outer periphery of the substrate S in the region R. The pitch of the plurality of static charge eliminators NDL is desirably as small as possible, and falls within, for example, the range of 10 μm to 100 mm. By arranging the plurality of static charge eliminators NDL in this way, even after the mold-separating operation of any shot region on the substrate S, it is possible to make any of the plurality of static charge eliminators NDL approach the mold M (pattern region PR) during the movement of the stage ST from the shaping position X1 to the supply position X2. That is, it is possible to reliably remove the electric-charge from the mold M. Note that this embodiment has explained the example in which the plurality of static charge eliminators NDL are provided on the stage ST, but only one static charge eliminator NDL may be provided on the stage ST.

It is known that the static charge eliminator NDL generally wears every time discharge is repeated. Therefore, for example, to operate the apparatus for a long period of several years or more, it is necessary to periodically replace the static charge eliminator NDL. Therefore, as shown in FIG. 2, in the imprint apparatus IMP according to this embodiment, the plurality of static charge eliminators NDL are assembled to a static charge eliminator holder NH, and the static charge eliminator holder NH is attached to the stage ST. With this configuration, when it is necessary to replace the static charge eliminators NDL, the plurality of static charge eliminators NDL can be detached from the stage ST or attached to the stage ST at once, and thus the plurality of static charge eliminators NDL can be replaced easily.

As described above, the imprint apparatus IMP according to this embodiment includes, in the stage ST, the electrically-conductive member NDL for removing the electric-charge from the mold M in a non-contact manner. The electrically-conductive member NDL protrudes from the stage ST (for example, the upper surface of the stage ST), and is configured to approach the mold M by the movement of the stage ST to cause discharge from the mold M. Thus, with the simple configuration, it is possible to efficiently remove the electric-charge from the mold M charged by separation charging through the mold-separating operation without degrading the productivity of the apparatus.

### Second Embodiment

The second embodiment according to the present disclosure will be described. In the above-described first embodiment, the static charge eliminator NDL is grounded. However, this embodiment will describe an example in which a static charge eliminator NDL is charged in a polarity opposite to that in which a mold M is charged. Note that this embodiment basically inherits the first embodiment and can follow the first embodiment except for matters referred to below.

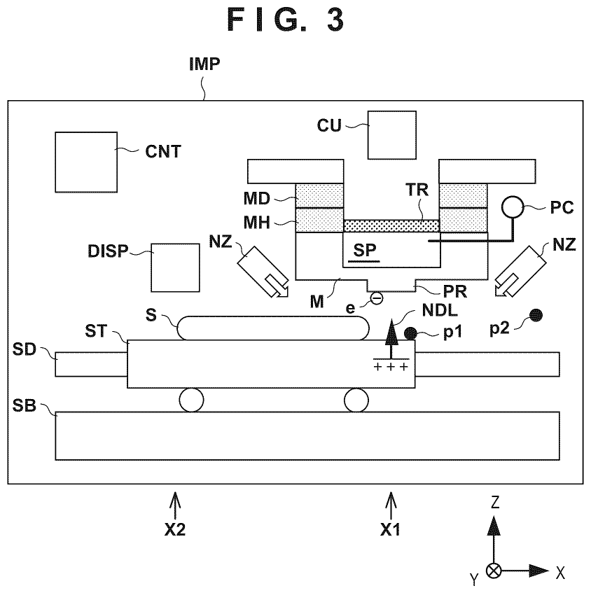

FIG. 3 is a schematic view showing an example of the configuration of an imprint apparatus IMP according to this embodiment. In this embodiment, the static charge eliminator NDL is not grounded, and is charged in a polarity opposite to that in which the mold M is charged. FIG. 3 shows an example in which the mold M is negatively charged and the static charge eliminator NDL is positively charged. However, the polarity in which the static charge eliminator NDL is charged is not limited to the positive polarity and may be the negative polarity. As described above, whether the mold M is easily charged positively or negatively can be decided based on a combination of the material of the mold M and an imprint material. If, for example, it is known, by a preliminary experiment or the like, whether the mold M is easily charged positively or negatively, the static charge eliminator NDL can be charged in a polarity opposite to that in which the mold M is charged. Since this can increase the potential difference between the mold M and the static charge eliminator NDL, discharge from the mold M to the static charge eliminator NDL is readily caused, thereby making it possible to more reliably remove an electric-charge from the mold M.

### Third Embodiment

The third embodiment according to the present disclosure will be described. This embodiment will describe a configuration further including an adjustment mechanism AM that adjusts the protrusion amount of a static charge eliminator NDL from a stage ST. Note that this embodiment basically inherits the first embodiment and can follow the first embodiment except for matters referred to below. In this embodiment, with respect to the polarity in which the static charge eliminator NDL is charged, the second embodiment may be applied, instead of the first embodiment.

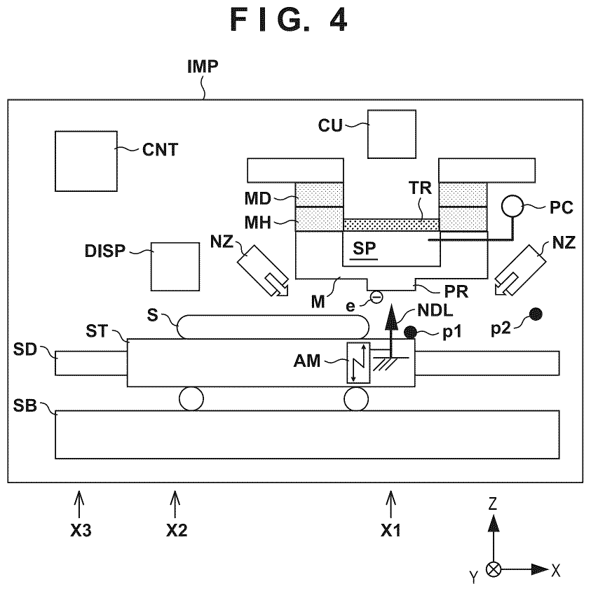

FIG. 4 is a schematic view showing an example of the configuration of an imprint apparatus IMP according to this embodiment. As shown in FIG. 4, the imprint apparatus IMP according to this embodiment can include the adjustment mechanism AM that adjusts the protrusion amount of the static charge eliminator NDL from the stage ST (for example, the upper surface of the stage ST). The adjustment mechanism AM can be configured to adjust the protrusion amount of the static charge eliminator NDL from the stage ST by driving the static charge eliminator NDL in the Z direction (vertical direction or height direction) under the control of a controller CNT. For example, in a state in which the static charge eliminator NDL is driven to the limit (upper limit) in the +Z direction by the adjustment mechanism AM, that is, a state in which the protrusion amount of the static charge eliminator NDL from the stage ST is maximum, the tip of the static charge eliminator NDL can protrude to the mold side more than the upper surface of a substrate S. On the other hand, in a state in which the static charge eliminator NDL is driven to the limit (lower limit) in the −Z direction by the adjustment mechanism AM, that is, a state in which the protrusion amount of the static charge eliminator NDL from the stage ST is minimum, the tip of the static charge eliminator NDL protrudes to the mold side not more than the upper surface of the substrate S.

By making it possible to adjust the protrusion amount of the static charge eliminator NDL from the stage ST, it is possible to make the static charge eliminator NDL closer to a mold M, thereby causing discharge from the mold M to the static charge eliminator NDL more easily. By decreasing the protrusion amount of the static charge eliminator NDL from the stage ST during an imprint process, movement of the stage ST, or the like, it is possible to avoid the static charge eliminator NDL from contacting the mold M, and avoid damage to the mold M and dust generation caused by contact between the mold M and the static charge eliminator NDL.

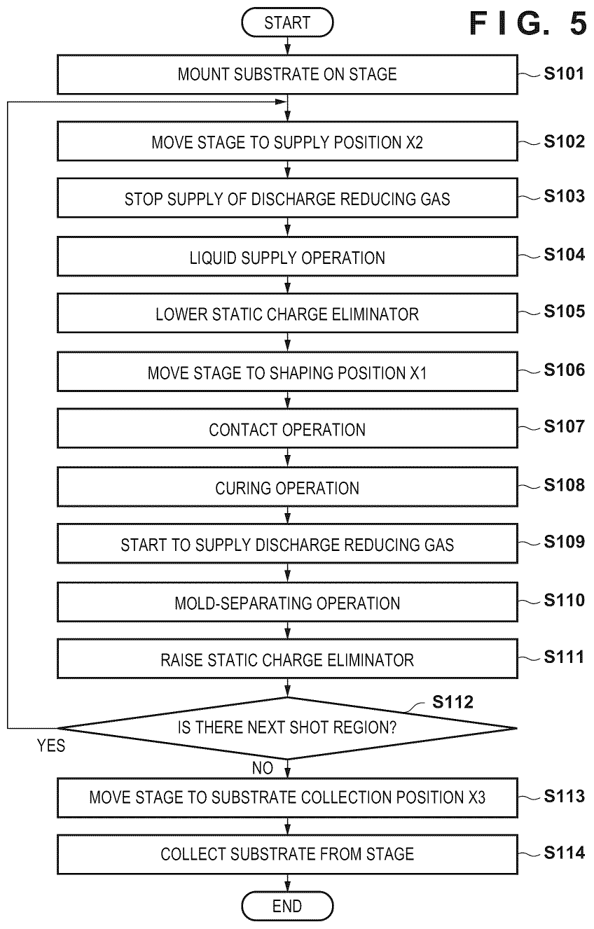

FIG. 5 is a flowchart (sequence) illustrating an imprint process performed for each shot region of the substrate S. An example of executing the adjustment operation of the protrusion amount of the static charge eliminator NDL in the imprint process will be described but the adjustment operation may be omitted. The flowchart shown in FIG. 5 can be executed by the controller CNT.

In step S101, the controller CNT moves the stage ST to a substrate mounting position (not shown) by a substrate driving mechanism SD and mounts the substrate S on the stage ST using a substrate conveyance mechanism (not shown). The substrate mounting position is a position where the substrate is mounted (loaded) on the stage ST. After the substrate S is mounted on the stage ST, the process advances to step S102, and the controller CNT moves the stage ST to a supply position X2 by the substrate driving mechanism SD. Next, in step S103, the controller CNT stops supply of a discharge reducing gas to the periphery of the mold M by a gas supplier NZ. Thus, during a period from a liquid supply operation to a curing operation to be described later, the periphery of an imprint material on the substrate S is not filled with the discharge reducing gas (for example, a dry gas), and it is thus possible to reduce concern about the filling property of the imprint material in the concave-convex pattern of the mold M being degraded. Note that if the supply of the discharge reducing gas to the periphery of the mold M by the gas supplier NZ is already stopped, step S103 may be skipped.

In step S104, the controller CNT supplies the imprint material onto the substrate S by a dispenser DISP (liquid supply operation). The liquid supply operation is performed for a shot region (to be sometimes referred to as a target shot region hereinafter) to undergo the imprint process among the plurality of shot regions on the substrate S. After the end of the liquid supply operation, the process advances to step S105, and the controller CNT decreases the protrusion amount of the static charge eliminator NDL from the stage ST by the adjustment mechanism AM (that is, the controller CNT lowers the static charge eliminator NDL). In the imprint process (for example, a contact process), this can avoid the static charge eliminator NDL from contacting the mold M, and avoid damage to the mold M and dust generation caused by contact between the mold M and the static charge eliminator NDL. Note that in a state in which the protrusion amount of the static charge eliminator NDL from the stage ST is already decreased, step S105 may be skipped.

In step S106, the controller CNT moves the stage ST to a shaping position X1 by the substrate driving mechanism SD. For example, the controller CNT moves the stage ST to the shaping position X1 by the substrate driving mechanism SD so that the target shot region is arranged below the pattern region PR of the mold M. After moving the stage ST to the shaping position X1, the process advances to step S107, and the controller CNT brings the pattern region PR of the mold M into contact with the imprint material on the substrate S by driving the mold M in the −Z direction by the mold driving mechanism MD (contact operation). Next, in step S108, the controller CNT performs alignment between the substrate S and the mold M, and then cures the imprint material by the curing unit CU in a state in which the mold M and the imprint material on the substrate S are in contact with each other (curing operation). After the end of the curing operation, the process advances to step S109, and the controller CNT starts to supply the discharge reducing gas to the periphery of the mold M by the gas supplier NZ.

In step S110, the controller CNT separates the mold M from the cured imprint material on the substrate S by driving the mold M in the +Z direction by the mold driving mechanism MD (mold-separating operation). After the end of the mold-separating operation, the process advances to step S111, and the controller CNT increases the protrusion amount of the static charge eliminator NDL from the stage ST by the adjustment mechanism AM (that is, the controller CNT raises the static charge eliminator NDL). Thus, as will be described later, during the movement of the stage ST from the shaping position X1 to the supply position X2 or a substrate collection position X3, it is possible to make the static charge eliminator NDL close to the mold M as much as possible to the extent that the static charge eliminator NDL does not contact the mold M, thereby easily causing discharge from the mold M to the static charge eliminator NDL.

In step S112, the controller CNT determines whether there is a shot region (to be sometimes referred to as a next shot region hereinafter) that has not undergone the imprint process among the plurality of shot regions on the substrate S. If there is the next shot region, the process advances to step S102, and the controller CNT moves the stage ST to the supply position X2 by the substrate driving mechanism SD to execute the imprint process for the next shot region as the target shot region. As described above, while the stage ST is moved from the shaping position X1 to the supply position X2, the static charge eliminator NDL in the stage in which the protrusion amount from the stage ST is increased approaches the mold M, thereby removing an electric-charge from the mold M. On the other hand, if there is no next shot region, the process advances to step S113.

In step S113, the controller CNT moves the stage ST to the substrate collection position X3 by the substrate driving mechanism SD. The substrate collection position X3 is a position (second position) where the substrate S is collected (unloaded) from the stage ST, and is set in the −X direction (first direction) when viewed from the shaping position X1, as shown in FIG. 4. Therefore, while the stage ST is moved from the shaping position X1 to the substrate collection position X3, the static charge eliminator NDL in a state in which the protrusion amount from the stage ST is increased approaches the mold M, thereby removing an electric-charge from the mold M. Next, in step S114, the controller CNT collects the substrate S from the stage ST using the substrate conveyance mechanism (not shown).

### Fourth Embodiment

The fourth embodiment according to the present disclosure will be described. In this embodiment, a planarization apparatus as a shaping apparatus will be described. Note that this embodiment basically inherits the first embodiment and can follow the first embodiment except for matters referred to below. In this embodiment, with respect to the polarity in which a static charge eliminator NDL is charged, the second embodiment may be applied, instead of the first embodiment, or the adjustment mechanism AM described in the third embodiment may be applied.

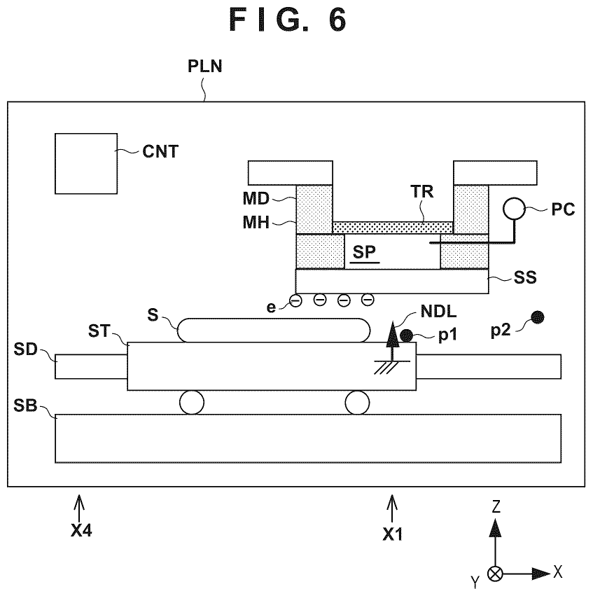

FIG. 6 is a schematic view showing an example of the configuration of a planarization apparatus PLN according to this embodiment. As shown in FIG. 6, the planarization apparatus PLN performs a contact operation and a mold-separating operation using a mold including a flat surface, instead of the mold M including the pattern region PR where the concave-convex pattern is formed. The mold including the flat surface is also called a planarization member, a flat template, or a superstrate, and will sometimes be referred to as a planarization member SS hereinafter. The planarization member SS is held by a mold holder MH. The planarization apparatus PLN according to this embodiment can planarize a composition on a substrate S by curing the composition on the substrate S in a state in which the flat surface of the planarization member SS and the composition are in contact with each other and separating the planarization member SS from the cured composition. That is, a planarization film made of a cured product of the composition can be formed on the substrate S. Note that the configuration and operation of the planarization apparatus PLN other than that the planarization member SS is held by the mold holder MH are the same as those of the imprint apparatus IMP described in the first to third embodiments.

The lower surface of the planarization member SS can have substantially the same area as that of the surface of the substrate S. In this case, the planarization apparatus PLN can perform a contact operation for the entire surface (entire region) of the substrate S at once (collectively) using the planarization member SS. After the contact operation for planarization, a curing operation is performed, and the planarization member SS is separated from the cured composition on the substrate S (mold-separating operation). At this time, the planarization member SS can be charged. As described above, the planarization apparatus PLN can planarize the entire surface of the substrate S at once.

A particle p1 adhered to a stage ST and a particle p2 floating in an atmospheric space can exist around the planarization member SS. If the particles p1 and p2 and the planarization member SS are charged in opposite polarities (positive and negative polarities), the particles p1 and p2 can be attracted to the planarization member SS by an electrostatic force. If a planarization process of the next substrate S is performed using the planarization member SS to which the particles are adhered, a defect may occur in a planarization film formed on the substrate S. On the other hand, if electric-charges are removed from the planarization member SS, even if the particles p1 and p2 around the planarization member SS are charged, the possibility that the particles p1 and p2 are attracted to the planarization member SS is low. Therefore, it is possible to reduce adherence of the particles to the planarization member SS.

To planarize the entire surface of the substrate S at once, the planarization apparatus PLN according to this embodiment needs to replace the planarized substrate S on the stage ST by a new substrate S. The substrate S on the stage ST is replaced by a substrate conveyance mechanism (not shown) such as a conveyance hand in a state in which the stage ST is arranged at a substrate replacement position X4. The substrate replacement position X4 can be a position (second position) where the substrate S is collected (unloaded) from the stage ST and a position where the new substrate S is mounted (loaded) on the stage ST. The substrate replacement position X4 is set in the −X direction (first direction) when viewed from a shaping position X1 (first position). After the planarization process (for example, the mold-separating operation) is performed for the substrate S on the stage ST at the shaping position X1, the stage ST moves from the shaping position X1 toward the substrate replacement position X4 in the −X direction to replace the substrate S on the stage ST.

As described in the first embodiment (for example, see FIG. 2), the static charge eliminator NDL is arranged in the region R of the stage ST on the second direction side (+X direction side) of the virtual plane VP. Therefore, the static charge eliminator NDL approaches the charged planarization member SS in a non-contact state by the movement of the stage ST from the shaping position X1 toward the substrate replacement position X4 in the first direction (−X direction). At this time, electric-charges e charged to the planarization member SS can be emitted (discharged) to the static charge eliminator NDL. Since the static charge eliminator NDL is grounded, the electric-charges e emitted from the planarization member SS flow into the ground portion connected to the static charge eliminator NDL, and are thus removed from the planarization member SS. Since the static charge eliminator NDL approaches the planarization member SS during the movement of the stage ST from the shaping position X1 to the substrate replacement position X4, the productivity (throughput) of the apparatus does not decrease. That is, with a simple configuration, the planarization apparatus PLN according to this embodiment can efficiently remove the electric-charges from the planarization member SS charged by separation charging through the mold-separating operation without degrading the productivity of the apparatus.

### Embodiment of Article Manufacturing Method

An article manufacturing method according to the embodiment of the present disclosure is suitable for manufacturing an article, for example, a microdevice such as a semiconductor device or a device having a microstructure. The article manufacturing method according to this embodiment includes a shaping step of shaping a composition on a substrate using the above-described shaping apparatus (imprint apparatus or planarization apparatus), a processing step of processing the substrate having the composition shaped in the shaping step, and a manufacturing step of manufacturing an article from the substrate processed in the processing step. The manufacturing method further includes other known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article.

The pattern of a cured product shaped using the above-described shaping apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. Examples of the mold are a mold for imprint and the like.

The pattern of the cured product is directly used as the constituent member of at least some of the above-described articles or used temporarily as a resist mask. After etching or ion implantation is performed in the processing step of the substrate, the resist mask is removed.

[Article Manufacturing Method using Imprint Apparatus]

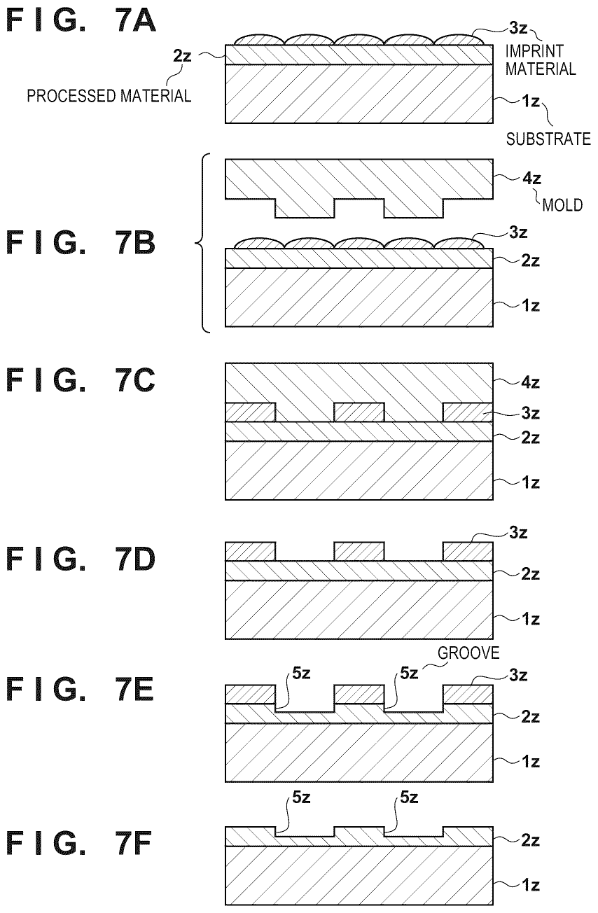

Next, a specific method of manufacturing an article using an imprint apparatus as the shaping apparatus will be described. As shown in FIG. 7A, a substrate 1z such as a silicon wafer with a target material 2z to be processed, such as an insulator, formed on the surface is prepared. Next, an imprint material 3z is applied to the surface of the target material 2z by an inkjet method or the like. A state in which the imprint material 3z is applied as a plurality of droplets onto the substrate is shown here.

As shown in FIG. 7B, a side of a mold 4z for imprint, where a pattern with concave and convex portions is formed, is directed to face the imprint material 3z on the substrate. As shown in FIG. 7C, the mold 4z and the substrate 1z to which the imprint material 3z is applied are brought into contact with each other, and a pressure is applied. The gap between the mold 4z and the target material 2z is filled with the imprint material 3z. In this state, by irradiating the imprint material 3z with energy for curing through the mold 4z, the imprint material 3z is cured.

As shown in FIG. 7D, after the imprint material 3z is cured, the mold 4z is separated from the substrate 1z. Then, the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the pattern with concave and convex portions in the mold 4z is transferred to the imprint material 3z.

As shown in FIG. 7E, by performing etching using the pattern of the cured product as an etching resistant mask, a portion of the surface of the target material 2z where the cured product does not exist or remains thin is removed to form a groove 5z. As shown in FIG. 7F, by removing the pattern of the cured product, an article with the grooves 5z formed in the surface of the target material 2z can be obtained. Here, the pattern of the cured product is removed. However, instead of removing the pattern of the cured product after processing, it may be used as, for example, an interlayer dielectric film included in a semiconductor element or the like, that is, a constituent member of an article.

[Article Manufacturing Method using Planarization Apparatus]

In the above-described embodiment, a circuit pattern transfer mold on which a pattern with concave and convex portions is formed has been described as the mold. However, the mold may be a mold (plane template) having, as the contact surface, a flat surface where no pattern with concave and convex portions is formed. The plane template is used in a planarization apparatus that performs a planarization process of performing shaping such that a composition on a substrate is planarized by the flat surface. The planarization process includes a step of curing a curable composition by light irradiation or heating in a state in which the flat surface (contact surface) of the plane template is in contact with the curable composition supplied onto the substrate. As described above, this embodiment can be applied to a forming apparatus configured to form a composition on a substrate using a plane template.

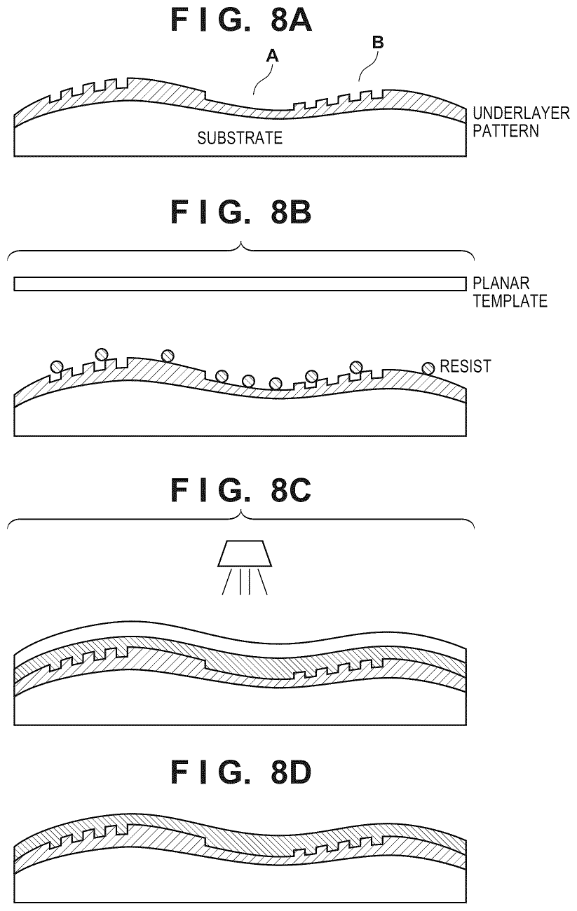

The underlying pattern on the substrate has an uneven profile derived from the pattern formed in the previous step. In particular, with the recent multilayered structure of a memory element, the substrate (process wafer) may have a step of about 100 nm. The step derived from a moderate undulation of the entire substrate can be corrected by the focus following function of an exposure apparatus (scanner) used in the photolithography step. However, an unevenness with a small pitch fitted in the exposure slit area of the exposure apparatus directly consumes the DOF (Depth Of Focus) of the exposure apparatus. As a conventional technique of planarizing the underlying pattern of a substrate, a technique of forming a planarization layer, such as SOC (Spin On Carbon) or CMP (Chemical Mechanical Polishing), is used. In the conventional technique, however, as shown in FIG. 8A, an unevenness suppressing rate of only 40% to 70% is obtained in the boundary portion between an isolated pattern region A and a repetitive dense (concentration of a line & space pattern) pattern region B, and sufficient planarization performance cannot be obtained. The unevenness difference of the underlying pattern caused by the multilayered structure tends to further increase in the future.

As a solution to this problem, U.S. Pat. No. 9,415,418 proposes a technique of forming a continuous film by application of a resist serving as a planarization layer by an inkjet dispenser and pressing by a plane template. Also, U.S. Pat. No. 8,394,282 proposes a technique of reflecting a topography measurement result on a substrate side on density information for each position to instruct application by an inkjet dispenser. An imprint apparatus IMP can particularly be applied as a planarization processing (planarization) apparatus for performing local planarization in a substrate surface by pressing a plane template as the mold against an uncured resist applied in advance.

FIG. 8A shows a substrate before planarization processing. In the isolated pattern region A, the area of a pattern convex portion is small. In the repetitive dense pattern region B, the ratio of the area of a pattern convex portion to the area of a pattern concave portion is 1:1. The average height of the isolated pattern region A and the repetitive dense pattern region B changes depending on the ratio of the pattern convex portion.

FIG. 8B shows a state in which the resist that forms the planarization layer is applied to the substrate. FIG. 8B shows a state in which the resist is applied by an inkjet dispenser based on the technique proposed in U.S. Pat. No. 9,415,418. However, a spin coater may be used to apply the resist. In other words, the imprint apparatus IMP can be applied if a step of pressing a plane template against an uncured resist applied in advance to planarize the resist is included.

As shown in FIG. 8C, the plane template is made of glass or quartz that passes ultraviolet light, and the resist is cured by irradiation of ultraviolet light from a light source. For the moderate unevenness of the entire substrate, the plane template conforms to the profile of the substrate surface. After the resist is cured, the plane template is separated from the resist, as shown in FIG. 8D.

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-093204 filed on Jun. 7, 2024, which is hereby incorporated by reference herein in its entirety.

What is claimed is:

1. A shaping apparatus for shaping a composition on a substrate using a mold, comprising:
a stage configured to move while holding the substrate; and
an electrically-conductive member protruding from the stage to remove an electric-charge from the mold in a non-contact manner,
wherein the electrically-conductive member is configured to approach the mold by the movement of the stage and cause discharge from the mold.

2. The apparatus according to claim 1, wherein
the stage can move between a first position where the composition on the substrate is shaped using the mold and a second position different from the first position, and
the electrically-conductive member is provided on the stage to approach the mold during the movement of the stage from the first position to the second position.

3. The apparatus according to claim 2, wherein
the second position is in a first direction when viewed from the first position, and
in a case where a virtual plane perpendicular to the first direction and passing through a center of gravity of the substrate is defined and a direction opposite to the first direction is defined as a second direction, the electrically-conductive member is provided in a region of the stage on the side of the second direction of the virtual plane.

4. The apparatus according to claim 3, wherein a plurality of electrically-conductive members are provided on the stage to surround the substrate in the region.

5. The apparatus according to claim 4, wherein the plurality of electrically-conductive members are arrayed along an outer periphery of the substrate in the region.

6. The apparatus according to claim 2, wherein the second position is a position where the composition is supplied onto the substrate.

7. The apparatus according to claim 2, wherein the second position is a position where the substrate on the stage is collected.

8. The apparatus according to claim 1, wherein the electrically-conductive member has a shape with a pointed tip on the side of the mold.

9. The apparatus according to claim 1, wherein the electrically-conductive member is grounded.

10. The apparatus according to claim 1, wherein the electrically-conductive member is charged in a polarity opposite to a polarity in which the mold is charged.

11. The apparatus according to claim 1, further comprising an adjustment mechanism configured to adjust a protrusion amount of the electrically-conductive member from the stage.

12. The apparatus according to claim 1, further comprising a gas supplier configured to supply, to a periphery of the mold, a gas for reducing a discharge phenomenon from the mold.

13. The apparatus according to claim 1, wherein
the mold includes a pattern surface on which a pattern is provided, and
the shaping apparatus is an imprint apparatus configured to form a pattern to the composition on the substrate by bringing the composition and the pattern surface of the mold into contact with each other.

14. The apparatus according to claim 1, wherein
the mold includes a flat surface, and
the shaping apparatus is a planarization apparatus configured to planarize the composition on the substrate by bringing the composition and the flat surface of the mold into contact with each other.

15. An article manufacturing method comprising:
shaping a composition on a substrate using a shaping apparatus defined in claim 1;
processing the substrate having the shaped composition; and
manufacturing an article from the processed substrate.
